(19) United States
(12) Patent Application Publication
(10) Pub. No.: US 2008/0122066 A1
(43) Pub. Date: May 29, 2008

(54) Semiconductor device

(75) Inventor: Kenichi Ishii, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kanagawa (JP)

(21) Appl. No.: 11/978,615

(22) Filed: Oct. 30, 2007

(30) Foreign Application Priority Data
Nov. 29, 2006 (JP) 2006-321590

(51) Int. Cl. H01L 23/06

(52) U.S. Cl. 257/703; 257/E23.191

(57) ABSTRACT

A semiconductor device having a CSP packaging structure, which exhibits a reduced thermal stress exerted on a semiconductor chip without deteriorating electrical characteristics, is provided. A semiconductor device comprises an electroconductive cap, functioning as an external coupling terminal and including a metallic member and a composite material; and a semiconductor chip, having a circuit surface constituting an external electrode and a metallized surface opposite to the circuit surface, wherein the metallic member of the electroconductive cap is electrically connected to the metallized surface of the semiconductor chip via an electroconductive junction material, without a presence of the composite material therebetween.

This application is based on Japanese patent application No. 2006-321590, the content of which is incorporated hereinto by reference.

### BACKGROUND

1. Technical Field

The present invention relates to a semiconductor device having a packaging structure.

2. Related Art

More sophisticated, more functional and more miniaturized electronic equipments are demanded in recent years, and an increased importance in the packaging technology with higher density is recognized for semiconductor integrated circuits serving as key devices that support the advanced electronic equipments. Typical packaging technology corresponding to a packaging technology with higher density for semiconductor integrated circuits includes a chip size package (hereinafter abbreviated as CSP) technology. CSP is a package having a dimension nearly equivalent to a bare chip, in which semiconductor integrated circuits are formed (hereinafter referred to as a semiconductor chip), and CSP technology is defined as a technology for housing semiconductor chips in the CSP.

An example of the CSP is a semiconductor device developed by International Rectifier, El Segundo, Calif., which is disclosed in Japanese Patent Laid-Open No. 2005-354105. The semiconductor device is characterized in that the configuration of the semiconductor device is helpful in miniaturizing a package of a power metal oxide semiconductor field effect transistor (power MOSFET), in addition to providing an improved packaging-ability and an improved heat release-ability of power MOSFET. The semiconductor device will be described below in detail.

The FIG. 7 illustrates a cross-sectional view of a semiconductor device 50. As shown in FIG. 7, a semiconductor chip 52 and a metallic cap 51 are connected via an electroconductive resin 54. The metallic cap 51 has a shape of an inverted concave-shape having a dimension that is slightly larger than a dimension of the semiconductor chip 52. A source electrode and an external coupling terminal 53 which is to couple to the gate electrode are formed in a circuit surface 52a of the semiconductor chip, and a drain electrode is formed in a back surface 52b of the semiconductor chip. The metallic cap 51 is equipotential with the drain electrode of the semiconductor chip 52 by the conductive resin 54. The external coupling terminal 53 is formed to be disposed to be coplanar with an end surface 51a of the metallic cap. Therefore, the drain electrode is formed on the same plane through the end surface 51a of the metallic cap, as the plane on which the source electrode and the gate electrode are also formed which are formed in the circuit surface 52a of the semiconductor chip. More specifically, since the source, the drain and the gate terminals of the semiconductor chip 52 can be reflow-soldered at the same time to the electrode pad on the printed circuit board, thereby providing an improved package-ability. Further, both sides of the semiconductor chip 52 in the semiconductor device^{TR} 50 are joined to a printed circuit board (not shown) and the metallic cap 51, both of which function as heat sinks, thereby providing an improved heat release-ability.

In addition to above, another type of the CSP characterized in exhibiting an improved heat release-ability is also disclosed in U.S. Pat. No. 5,789,809. U.S. Pat. No. 5,789,809 is directed to a CSP developed by National Semiconductor Inc., which is configured that a semiconductor chip is joined to an electroconductive cap so that an improved heat release-ability is achieved.

Further, Japanese Patent Laid-Open No. 2004-253703 discloses a semiconductor device including a semiconductor chip and a heat release member that is capable of releasing heat generated from the semiconductor chip. The heat release member is composed of copper (Cu), aluminum (Al), a composite material containing thereof as a basic material, or a carbon composite material. Also, a Cu post and a coupling material composed of tin (Sn) or the like are formed between the semiconductor chip and the heat release member.

The FIG. 8 illustrates a high output circuit device in fourth example of Japanese Patent Laid-Open No. 2006-54392. In such device, a carbon substrate 60 is composed of a composite member of a carbon material 61 and a metallic material 62. In FIG. 8, a power IC 68 is installed to the metallic material 62 via the carbon material 61, and the metallic material 62 also serves as a metallic cap 63. The power IC 68 is also coupled to an electric line 66 on a ceramics substrate via a coupling means of a bump solder 65 provided on the surface. In such device, the carbon material is a material produced by baking a caked carbon powder or a caked carbon fiber, and then impregnating the baked material with metals such as Cu, Al and the like, or powder-baking thereof. Since the carbon material 61 absorbs an internal stress even if the device is configured to have the power IC 68 deposited directly on the carbon material 61 in the device disclosed in Japanese Patent Laid-Open No. 2006-54392, and thus a breaking of the substrate 64 can be prevented.

However, when a component that emits a heat such as a power MOSFET is installed in a mother board, a stress created by a thermal expansion and a thermal shrinkage considerably affects the semiconductor chip. In particular, a difference in the structural materials induces a large difference in linear expansion coefficients in a soldered-joint section, causing a thermal stress. This, in turn, results in a crack or the like in solder, easily causing defective characteristics. For example, copper (Cu), which is a metallic material having an excellent thermal conductivity, is often employed for an electroconductive cap. Here, a linear expansion coefficient of Cu is 17 ppm/degree C. On the other hand, a linear expansion coefficient of silicon, which is employed for semiconductor chips, is 3 ppm/degree C., lead free solder exhibits 22 ppm/degree C., and a linear expansion coefficient of glass epoxy, which is employed for a material of a printed circuit board, is 20 ppm/degree C. Therefore, such difference in linear expansion coefficients induces a thermal stress, causing cracks in solder, resulting in a problem of a deteriorated long term reliability of products.

In order to solve such problem, a metallic cap or a heat release member may be employed as described in the above-listed related art documents to provide an improved heat releasing efficiency. Nevertheless, an improvement in relaxation of thermal stress is still required. In particular in ball grid array (BGA) semiconductor devices, a vary large stress is exerted over the soldered joint section, so that life of product is influenced. Therefore, it is necessary to reduce such stress as much as possible, in order to assure certain level of long term reliability of products. Further, when power electrodes or other electrodes are disposed on both sides of the semiconductor chip, it is preferable that the semiconductor package has an excellent electric conductivity. Therefore, it is also critical that the material employed for providing an improved heat release-ability or a reduced thermal stress does not reduce electrical characteristics of the semiconductor device.

A power IC is fixed to a metallic plate via a carbon material in fourth example of Japanese Patent Laid-Open No. 2006-54392, which is attempting to absorb a stress induced by a difference in thermal expansion coefficients between the materials. However, since an electric conductivity of the carbon material is hundreds times as low as that of Cu, the electric current path is shielded. Therefore, while an electric current flows, electric conductivity is deteriorated. On the other hand, it is preferable that a decrease in electric conductivity is minimized particularly in the case of the power MOSFET.

The present invention is achieved on the basis of the above-described circumstances, and provides a semiconductor device having a CSP packaging structure, which exhibits a reduced thermal stress exerted onto the semiconductor chip without deteriorating electrical characteristics.

### SUMMARY

According to one aspect of the present invention, there is provided a semiconductor device, comprising: an electroconductive cap, functioning as an external coupling terminal and including a metallic member and a composite material; and a semiconductor chip, having a circuit surface constituting an external electrode and a metallized surface opposite to the circuit surface, wherein the metallic member of the electroconductive cap is electrically connected to the metallized surface of the semiconductor chip via an electroconductive junction material, without a presence of the composite material therebetween.

Since the electroconductive cap contains the composite material, the composite material is capable of absorbing a thermal stress, so that the thermal stress created in the semiconductor device can be reduced. Further, a joined surface of the semiconductor chip, which is joined to the electroconductive cap, is metallized. Since the metallic member of the electroconductive cap is joined to the semiconductor chip in the metallized surface without a presence of the composite material intervened therebetween, electric current path to the semiconductor chip and to the base substrate is not blocked by the composite material, and thus a discontinuation of the electric current path is avoided. Therefore, according to the present invention, a continuous electric current path is ensured, a reduced thermal stress can be achieved without deteriorating electrical characteristics.

According to the present invention, a semiconductor device having a CSP packaging structure, which exhibits a reduced thermal stress generated in the semiconductor device without deteriorating electrical characteristics, can be provided. The present invention achieves a reduced thermal stress in the semiconductor device, so that the product lifetime of the device can be extended, thereby contributing to providing an improved quality of products.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 includes a cross-sectional view and a plan view from underneath, schematically illustrating a semiconductor device according to an embodiment;

FIG. 2 includes a cross-sectional view and a plan view from underneath, schematically illustrating a semiconductor device according to an embodiment;

FIG. 3 is a cross-sectional view, schematically illustrating a semiconductor device according to an embodiment;

FIG. 4 includes a cross-sectional view and a plan view from underneath, schematically illustrating a semiconductor device according to an embodiment;

FIG. 5 is a cross-sectional view, illustrating a semiconductor device according to another embodiment of the present invention;

FIG. 6 is a cross-sectional view, illustrating a semiconductor device according to yet other embodiment of the present invention;

FIG. 7 is a cross-sectional view, illustrating a conventional semiconductor device; and

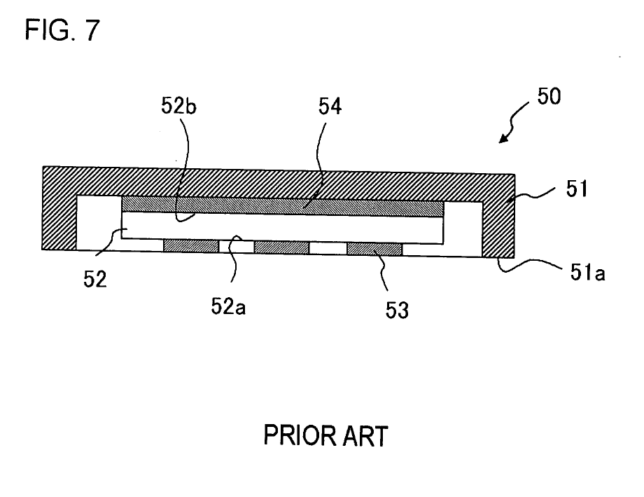

FIG. 8 is a cross-sectional view, illustrating a conventional semiconductor device.

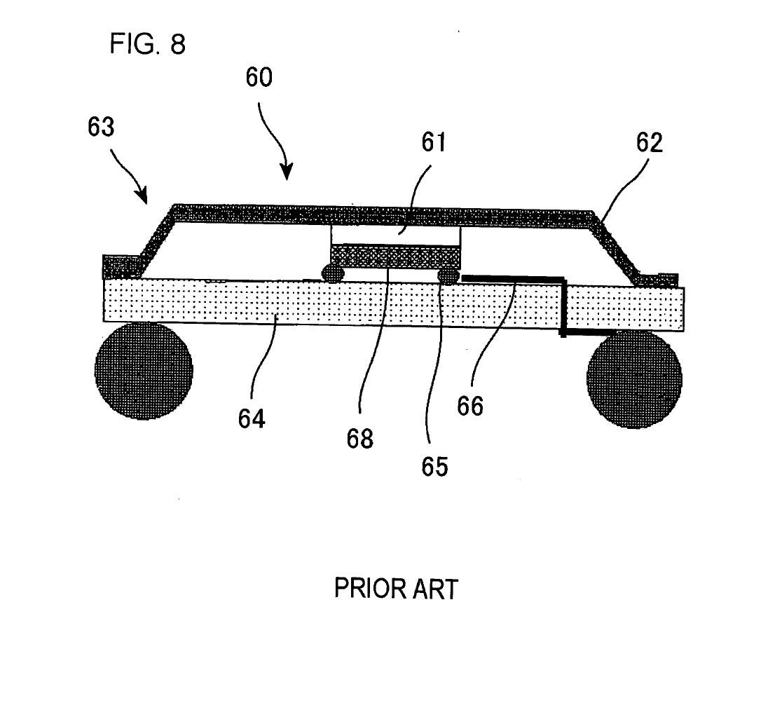

### DETAILED DESCRIPTION

The invention will now be described herein with reference to illustrative embodiments. Those skilled in the art will recognize that many alternative embodiments can be accomplished using the teachings of the present invention and that the invention is not limited to the embodiments illustrated for explanatory purposed.

Preferable exemplary implementations according to the present invention will be described in reference to the annexed figures. In all figures, an identical numeral is assigned to an element commonly appeared in the description of the present invention in reference to the figures, and the detailed description thereof will not be repeated.

### First Embodiment

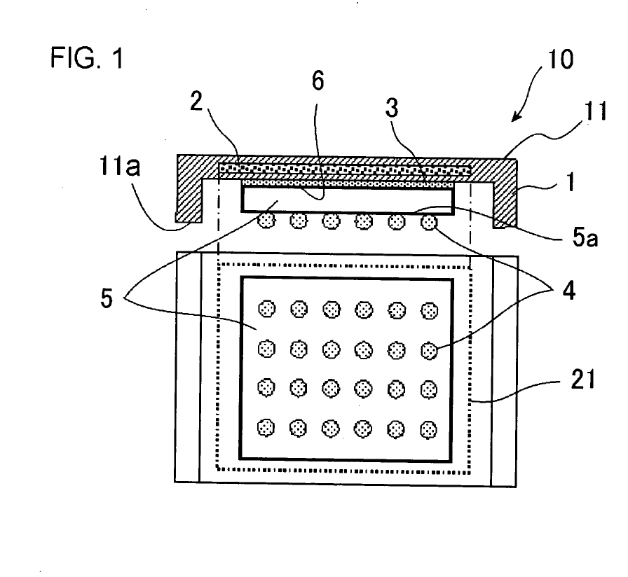

FIG. 1 includes a cross-sectional view and a plan view from underneath, illustrating a configuration of a semiconductor device 10 according to the present embodiment. As shown in FIG. 1, the semiconductor device 10 includes a semiconductor chip 5 and an electroconductive cap 11, and the electroconductive cap 11 includes a metallic member 1 and a composite material 2. The electroconductive cap 11 has an inverted concave-shape, which has a dimension slightly larger than a dimension of the semiconductor chip 5. The semiconductor chip 5 has a circuit surface 5a that constitutes an external electrode and a metallized surface 6 that is opposite to the circuit surface 5a. In the semiconductor device of the present embodiment, the external electrode of the semiconductor chip circuit surface 5a is coupled to, for example, a source electrode and a gate electrode of a MOSFET formed in the semiconductor chip 5. In addition, the metallized surface 6 corresponds to a drain electrode. The electroconductive cap 11 functions as an external coupling terminal, and the metallized surface 6 of the semiconductor chip 5 assures an electroconductivity with the electroconductive cap 11. The bottom of the electroconductive cap 11 is electrically connected to the metallized surface 6 of the semiconductor chip via an electroconductive junction material 3, and the electroconductive cap 11 is in an equipotential with a drain electrode of the semiconductor chip 5. In the present embodiment a solder material is employed for the electroconductive junction material 3. Here, the electroconductive cap 11 is connected to the metallized surface 6 of the semiconductor chip 5 with the solder material, without a presence of the composite material 2 therebetween. More specifically, the electroconductive cap 11 is joined to the semiconductor chip 5 via the solder material, by joining the metallic member 1 to the metallized surface 6. Therefore, the composite material 2 does not interfere the electric current path between the electroconductive cap 11 and the semiconductor chip 5. This configuration provides an electrically uninterrupted structure, so that a decrease in the electric conductivity can be prevented.

The semiconductor chip 5 is, for example, a bare chip having a MOSFET formed therein. The bare chip is obtained by dicing a wafer having MOSFET devices formed on a silicon base member into chips having a dimension of several square millimeters. The diced bare chips is joined to the electroconductive cap 11 having a dimension slightly larger than a dimension of the chip to provide the CSP having a dimension closer to the bare chip size, achieving an improved handle-ability. This results in facilitating a desired package without reducing a packaging density. Linear expansion coefficient of the semiconductor chip is, for example, about 3.0 to 3.5 ppm/degree C.

The electroconductive cap 11 includes the metallic member 1 and the composite material 2. Materials constituting the metallic member 1 may include, for example, metals such as copper (Cu), iron (Fe), aluminum (Al) and the like, or an alloy such as kovar and the like, and a material having a plated metal such as nickel, solder, gold and the like on the surface thereof. Alternatively, the metallic member may be composed of an electric conductive resin containing an electroconductive filler such as carbon and the like. Linear expansion coefficient of a metal constituting the electroconductive cap is, for example, about 16 to 17 ppm/degree C., and linear expansion coefficient of Cu is 17 ppm/degree C.

The electroconductive cap 11 contains the composite material 2. The composite material appeared in this specification means a material composed of two or more materials. The composite material employed here is contained in the electroconductive cap, for the purpose of reducing an influence of the thermal stress. For example, a composite material having linear expansion coefficient, which is lower than that of a metallic member constituting the electroconductive cap, and having Young's modulus, which is lower than that of the metallic member constituting the electroconductive cap, may be employed. The combination of the metallic member with the composite material provides a flexible structure of the cap as a whole having lower linear expansion coefficient and also provides a reduced influence of the thermal stress.

The composite material employed here is not particularly limited to any specific type of material and may be suitably selected, as long as the material is capable of reducing influence of the thermal stress, and a typical composite material may be, for example, a composite material having linear expansion coefficient within a range equal to or more than 4 ppm/degree C. and equal to or less than 10 ppm/degree C., and Young's modulus within a range equal to or more than 1 GPa and equal to or less than 30 GPa. An example of such composite material available here may be, for example, a composite material of black-lead and a metal.

A typical composite material of black-lead and a metal available here may be, for example, a metallic composite material, which is a sintered body of graphite particles impregnated with copper. Here, metallic materials employed for the impregnation may alternatively be aluminum (Al), in addition to copper. When the copper-impregnated black-lead is employed, linear expansion coefficient of the material is 4 to 7 ppm/degree C. and Young's modulus is about 10 GPa. Therefore, a reduced linear expansion coefficient, which is about one third of that of copper, which is closer to that of silicon, is achieved, thereby providing an improved stress relaxation. Further, Young's modulus, which is about one tenth of that of copper, is achieved, providing a flexible member. Furthermore, for an application such as IC or LSI package, which is unaffected by a higher specific resistance, an alternative composite material of carbon fiber may be employed, instead of black-lead. Such combination of the composite materials can achieve a reduction in the stress exerted on the soldered joint for the electrode in the chip surface by about 20%.

The composite material 2 is included in the metallic member 1 in a form that does not intercept the electric current path between the electroconductive cap 11 and the semiconductor chip 5. A location that the composite material 2 is included therein is not particularly limited to any specific location as long as the composite material 2 does not intercept the electric current path. For example, the composite material 2 may be embedded in an interior of the metallic member 1, as shown in FIG. 1. Typical method for manufacturing the electroconductive cap that contains the composite material buried in the interior thereof may be a method as described below. The following description will be made in reference to a configuration employing Cu for a metallic member. Copper (Cu) body, which serves as a core material of an electroconductive cap, is suitably drilled to form bores therein, and the bores are filed with a composite material. Thin Cu films are adhered on the front and the back surfaces of the Cu body, and then the body is pressed to obtain a base member. The base member is shaped and processed to a desired shape to obtain an electroconductive cap. The position of the composite material will be optimized, in consideration of the dimension of a semiconductor chip to be joined. Further, the thin Cu films provided on the front and the back surfaces of the composite material may also be manufactured via a metal plating process.

Since the metallic material employed for the metallic member of the electroconductive cap is thin, physical properties of the composite material are actualized. More specifically, an amount of deformation in the case of being exposed by a heat becomes low, and the electroconductive cap exhibits a flexibility. Therefore, a stress exerted on the semiconductor chip is decreased, and also a stress exerted on the connecting portion such as solder for connecting to mother board is decreased. Thus, a longer product lifetime can be obtained.

The metallized surface 6 on the back surface of the semiconductor chip is formed for the purpose of ensuring an electroconductivity between a circuit formed in the semiconductor chip 5 and the electroconductive cap 11. More specifically, the metallized portion serves as an electrode that couples the electric circuit formed in the semiconductor chip 5 with the electroconductive cap 11. For example, the metallized portion is employed for a drain contact of the MOSFET formed in the semiconductor chip 5. In the present embodiment, since the electroconductive cap 11 is connected to the semiconductor chip 5 via the solder material without a presence of the composite material 2 intervened, the electroconductive cap 11 functions as an external coupling terminal.

Further, the above-described metallized surface 6 may also be formed for the purpose of radiating a heat generated in the semiconductor chip 5 toward the electroconductive cap 11. As described above, the connection between the electroconductive cap 11 and the semiconductor chip 5 serves as providing a heat release, in addition to providing the mechanical fixing and the electric connection.

The metallized surface 6 is a metallic layer, which is formed on a surface of a circuit formed in the back surface of the semiconductor chip 5. Such metallic layer may be composed of a single layer, or have a multiple-layered structure of a plurality of metallic layers. When the metallized surface 6 is composed of a plurality of metallic layers, any configuration of the metallic layers may be employed. For example, metallic layers of titanium (Ti), nickel (Ni) and silver (Ag) layers that are stacked in series on the back surface of the semiconductor chip, or metallic layers of Ti, Ni and gold (Au) that are stacked in series thereon may be employed. The thickness of the metallized surface 6 is not particularly limited to any specific thickness, and generally several tens nm to several fÊm. For example, Ti is 0.02 fÊm, Ni is 0.5 fÊm, and Ag is 1 fÊm.

In the present embodiment, the drain electrode is formed on a plane, which also includes the source electrode and the gate electrode formed in the circuit surface 5a of the semiconductor chip 5, through the end surface 11a of the electroconductive cap, and these terminals can be reflow-soldered at the same time to the electrode pad on the printed circuit board. The device shown in FIG. 1 has a configuration, which can achieve disposing interconnects at higher density, as the solder balls 4 form a ball grid array (BGA), which provides an electric connection with the electrode pad disposed in the printed circuit board. In addition to the above, available solder material includes fluxless solder and lead-free solder. However, the material is not limited to solder, and a configuration related to a flip-chip coupling, such as employing a gold bump or employing anisotropic conductive film (ACF) therewith, may alternatively be adopted.

### Second Embodiment

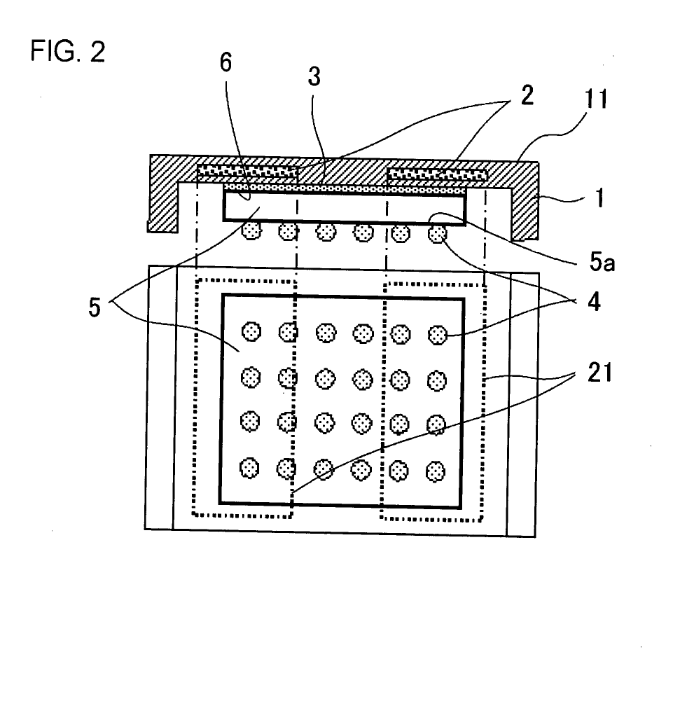

In another embodiment of the present invention, two or more pieces of the composite material 2 may be included in the metallic member 1. More specifically, as shown in FIG. 2, two or more pieces of the composite material 2 may be buried in the interior of the metallic member 1. The dimension of a composite material area 21 is smaller than that of first embodiment. The present embodiment is characterized in that the composite materials are arranged within necessity minimum areas. Such configuration would provide further reduced specific resistance of the electroconductive cap 11.

### Third Embodiment

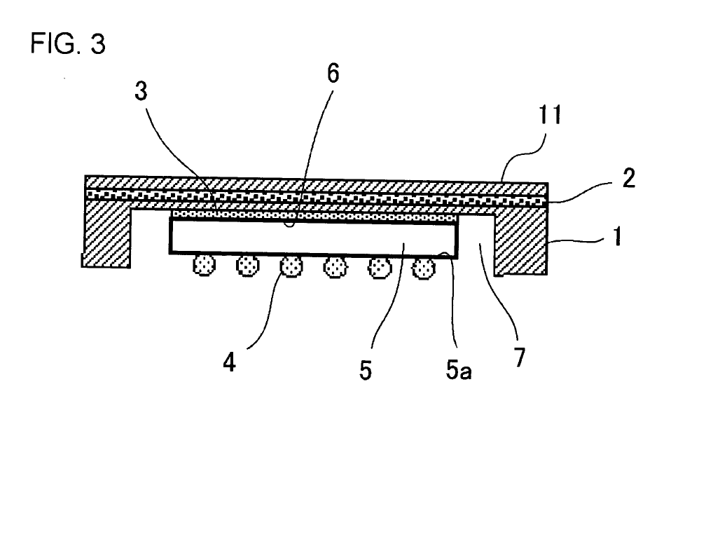

In the third embodiment, a semiconductor device may be configured as shown in FIG. 3. In FIG. 3, both sides of the composite material 2 is sandwiched with the metallic members 1 to provide a sandwich structure, in which the side surfaces of the composite material 2 are exposed. In FIG. 3, a cavity 7 is provided in the metallic member 1 to have a concave shape, so that the semiconductor chip 5 is housed.

### Fourth Embodiment

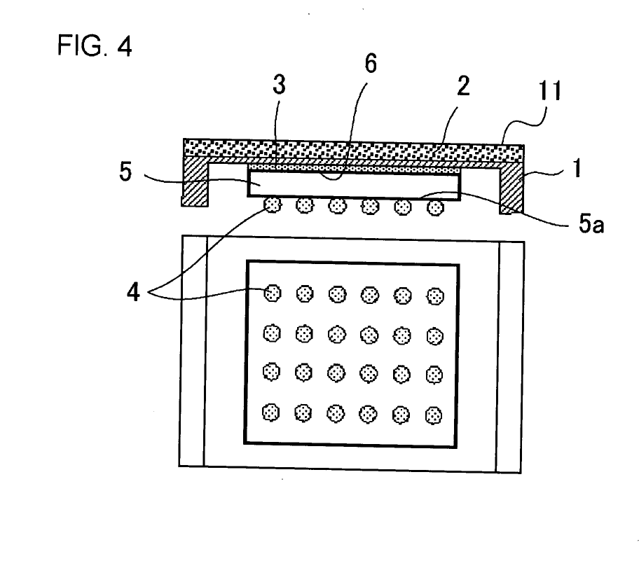

A semiconductor device of the fourth embodiment according to the present invention is shown in FIG. 4. The composite material 2 may be provided in a form, in which the composite material 2 is not interposed between the metallic member 1 and the semiconductor chip 5, and it is not necessarily being located in the interior of the metallic member 1. In the present embodiment, the composite material 2 is disposed on an outer surface of the electroconductive cap 11, and more specifically, on a surface of the metallic member 1 opposite to the surface where the semiconductor chip 5 is joined. In this configuration, the composite material 2 is exposed.

While the above-described embodiments illustrate the exemplary implementations of the present invention in reference to the annexed figures, various modifications other than that disclosed above may also be available.

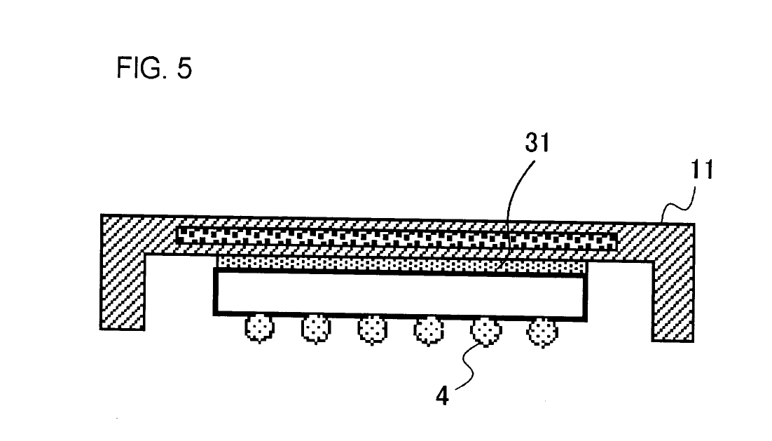

For example, while the above-described embodiment employs the solder material as the electroconductive junction material for joining the electroconductive cap to the semiconductor chip, the configuration is not limited thereto, and an electroconductive adhesive agent 31 may alternatively be employed (see FIG. 5).

While epoxy resins are often employed as an adhesive resin for an electroconductive adhesive agent, silicon resins, polyimide resins, acrylic resins and polyurethane resins may also be employed. While silver is often employed for the electroconductive filler, carbon, copper or the like may also be employed. The electroconductive adhesive agents generally have higher elastic modulus than solder, and is excellent in flexibility. In addition, since the electroconductive filler is contained therein, excellent thermal conductivity is exhibited.

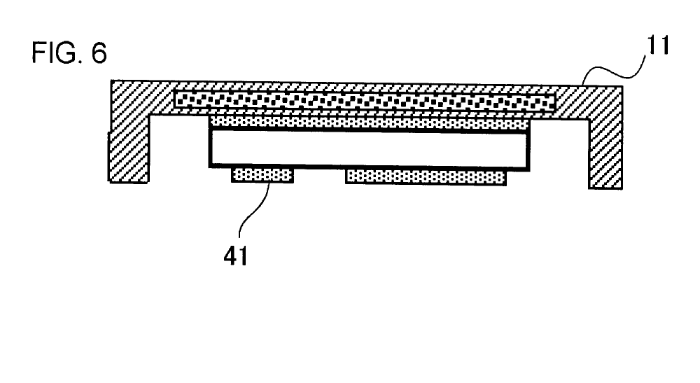

While the structure of the BGA formed of the solder balls 4 is illustrated in the above-described embodiments, an electrode geometry having solder bumps 41 formed therein may alternatively be employed, as shown in FIG. 6.

What is claimed is:

1. A semiconductor device, comprising:
an electroconductive cap, functioning as an external coupling terminal and including a metallic member and a composite material; and
a semiconductor chip, having a circuit surface constituting an external electrode and a metallized surface opposite to said circuit surface,
wherein said metallic member of said electroconductive cap is electrically connected to said metallized surface of said semiconductor chip via an electroconductive junction material, without a presence of said composite material therebetween.

2. The semiconductor device as set forth in claim 1, wherein said composite material is buried in the interior of said metallic member.

3. The semiconductor device as set forth in claim 1, wherein said composite material is two or more pieces of said composite materials.

4. The semiconductor device as set forth in claim 1, wherein said composite material is included in said metallic member in a form of a sandwiched structure, in which the composite material are sandwiched with said metallic members from both sides thereof, and wherein a side surface of said composite material is exposed.

5. The semiconductor device as set forth in claim 1, wherein said composite material is disposed on a surface of said metallic member that is opposite to the surface of said metallic member having said semiconductor chip connected thereto.

6. The semiconductor device as set forth in claim 1, wherein linear expansion coefficient of said composite material is lower than linear expansion coefficient of said metallic member and Young's modulus of said composite material is lower than Young's modulus of said metallic member.

7. The semiconductor device as set forth in claim 1, wherein said composite material has linear expansion coefficient within a range equal to or more than 4 ppm/degree C. and equal to or less than 10 ppm/degree C., and Young's modulus within a range equal to or more than 1 GPa and equal to or less than 30 GPa.

8. The semiconductor device as set forth in claim 1, wherein said composite material is a composite material of black-lead and a metal.

9. The semiconductor device as set forth in claim 1, wherein said composite material is a composite material, which is a sintered body of graphite particles impregnated with copper.

10. The semiconductor device as set forth in claim 1, wherein said electroconductive junction material is a solder material.

11. The semiconductor device as set forth in claim 1, wherein said electroconductive junction material is an electroconductive adhesive agent.
